(19) United States
(12) Patent Application Publication
(10) Pub. No.: US 2009/0102045 A1
(43) Pub. Date: Apr. 23, 2009

(54) Packaging substrate having capacitor embedded therein

(75) Inventors: Shih-Ping Hsu, Sinfong Township (TW); Wen-Sung Chang, Sinfong Township (TW); Chih-Kui Yang, Sinfong Township (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/285,957

(22) Filed: Oct. 17, 2008

(30) Foreign Application Priority Data
Oct. 17, 2007 (TW) 096138831

(51) Int. Cl. H01L 23/12

(52) U.S. Cl. 257/701

(57) ABSTRACT

A packaging substrate having capacitors embedded therein, comprising: two capacitor disposition layers, each respectively consisting of a high dielectric layer and two first circuit layers disposed on two opposite surfaces of the high dielectric layer, wherein each of the first circuit layers has a plurality of electrode plates and a plurality of circuits; an adhesive layer disposed between the capacitor disposition layers to adhere the capacitor disposition layers to form a core board structure, wherein spaces between the circuits of every first circuit layer are filled with the adhesive layer; and a plurality of conductive through holes penetrating the capacitor disposition layers and the adhesive layer, and electrically connecting the circuits of the capacitor disposition layers respectively; wherein, pairs of the electrode plates on the opposite surfaces of each of the capacitor disposition layers are parallel and correspond to each other to form capacitors.

### BACKGROUND OF THE INVENTION

1. Field of the Invention

The present invention relates to a packaging substrate having capacitor embedded therein and, more particularly, to a packaging substrate having a capacitor embedded therein which can solve the problem that a thin core is difficult to be processed.

2. Description of Related Art

Customer demands of the electronics industry continue to evolve rapidly, and the main trends of electronic devices focus on multiple functions and high performance. Moreover, in order to satisfy the requirements for high integration and miniaturization, packaging substrates have transferred from single-layered boards to multiple-layered boards, so that plenty of circuits and electronic components can be disposed in the same volume unit of the substrate. However, as the semiconductor devices have been progressively integrated, the number of pins of the package structure has increased at the same time. The increase on the number of pins and circuits may in turn cause the noise to be raised. Hence, passive components, such as resistors, capacitors, and inductors, are applied in the semiconductor package structure to diminish the noise or electrically compensate and stabilize the circuits. Therefore, the assembled semiconductor chip can meet the requirement for electrical property.

In the conventional method for manufacturing the packaging substrate, many passive components are mounted on the surface of the substrate by surface mount technology (SMT) in order to follow the trend towards miniaturization. However, when the packaging substrate is manufactured by SMT, it is hard to change the arrangement of capacitors and circuits, and the volume of the packaging substrate is hard to be reduced.

Recently, it is found that the method of lamination can solve the aforementioned problems, wherein a high dielectric material is sandwiched in copper layers to manufacture circuits, and then a capacitor is obtained. FIG. 1 is a cross-sectional view for illustrating a structure which has a capacitor formed therein by a method of lamination. With reference to FIG. 1, an inner circuit board 10 is provided, wherein the inner circuit board 10 has an inner circuit layer 11 comprising a lower electrode plate 111. A high dielectric layer 12 is formed on the inner circuit layer 11. Then, an outer circuit layer 13 is formed on the surface of the high dielectric layer 12, wherein the outer circuit layer 13 comprises an upper electrode plate 131. Hence, the upper electrode plate 111, the lower electrode plate 131, and a part of high dielectric layer 12 disposed between the upper electrode plate 111 and the lower electrode plate 131, combinedly serve as a capacitor 17. A conductive through hole 14 is formed to electrically connect the inner circuit layer 11 and the outer circuit layer 13. Then, some following processes are performed to form a solder mask 15, wherein the solder mask 15 has a plurality of openings 151 to expose a part of the outer circuit layer 13, which can serve as a conductive pad 132.

However, there are some disadvantages about the aforementioned method. First, the content of ceramic fillers in the high dielectric layer is high, which results in poor fluidity of the high dielectric layer. When the thickness of the inner circuit layer is increased or the thickness of the high dielectric layer is reduced, some voids or dimples may be easily generated in the high dielectric layer in spaces between the circuits of the inner circuit layer 11. Second, the content of gel in the high dielectric material is low, which may cause poor reliability of the adhesion between the inner circuit layer and the high dielectric layer. Third, the thickness of the high dielectric layer is less than 30 μm, and there are no glass fibers to enhance the structure of the high dielectric layer. Hence, when circuit layers are formed on the two surfaces of the high dielectric layer respectively, the high dielectric layer may easily crack due to there being no enough support from copper foils formed on the two surfaces of the dielectric layer. Therefore, it is desirable to provide a packaging substrate to solve the aforementioned problems.

### SUMMARY OF THE INVENTION

In view of the aforementioned problems, the object of the present invention is to provide a packaging substrate having capacitors embedded therein to diminish voids generated in a high dielectric material, improve the reliability of the adhesion between the high dielectric material and a circuit layer, and to solve the problem that the high dielectric material easily cracks during the process of manufacture.

To achieve the object, the present invention provides a packaging substrate having capacitors embedded therein, which comprises: two capacitor disposition layers, each respectively consisting of a high dielectric layer and two first circuit layers disposed on two opposite surfaces of the high dielectric layer respectively, wherein each of the first circuit layers has a plurality of electrode plates and a plurality of circuits; an adhesive layer disposed between the capacitor disposition layers to adhere the capacitor disposition layers to form a core board structure, wherein spaces between the circuits of every first circuit layer are filled with the adhesive layer; and a plurality of conductive through holes penetrating the capacitor disposition layers and the adhesive layer, and electrically connecting the circuits of the capacitor disposition layers respectively; wherein, pairs of the electrode plates on the opposite surfaces of each of the capacitor disposition layers are parallel and correspond to each other to form capacitors.

In the aforementioned structure, each of the capacitor disposition layers further comprises a plurality of conductive vias to electrically connect the two first circuit layers thereof. Besides, the material of the high dielectric layer is selected from polymer material, ceramic material, polymer material filled with ceramic powders, or a combination thereof.

In addition, the aforementioned packaging substrate further comprises two built-up structures respectively disposed on two opposite surfaces of the core board structure, wherein each of the two built-up structures comprises at least one dielectric layer, a second circuit layer disposed on the dielectric layer, and a plurality of conductive vias respectively, the outmost second circuit layer has a plurality of conductive pads, and at least parts of the conductive vias electrically connect to the first circuit layers of the core board structure. Besides, the aforementioned packaging substrate further comprises a solder mask disposed on the surfaces of the two built-up structures, wherein the solder mask has a plurality of openings to expose the conductive pads of the two built-up structures.

Furthermore, the present invention provides a method for manufacturing a packaging substrate having capacitors embedded therein, which comprises the following steps: providing two capacitor disposition layers, each of which respectively consisting of a high dielectric layer and two metal layers disposed on two opposite surfaces of the high dielectric layer; patterning the metal layer of the two capacitor disposition layers to form a first circuit layer, which has a plurality of electrode plates and a plurality of circuits; laminating an adhesive layer between the capacitor disposition layers to adhere the capacitor disposition layers to form a core board structure, wherein spaces between the circuits of every first circuit layer are filled with the adhesive layer; and forming a plurality of conductive through holes penetrating the capacitor disposition layers and the adhesive layer of the core board structure, and electrically connecting the circuits of the capacitor disposition layers respectively; wherein the electrode plates on the opposite surfaces of each of the capacitor disposition layers are parallel and correspond to each other to form a capacitor.

The aforementioned method may further comprise a step of: providing another capacitor disposition layer, wherein two first circuit layers are formed on the two surfaces of the capacitor disposition layer, the capacitor disposition layer is disposed between the other two capacitor disposition layers; and sandwiching in adhesion layers by lamination to adhere the three capacitor disposition layers to form a core board structure.

In the aforementioned method, each of the capacitor disposition layers further comprise a plurality of conductive vias to electrically connect the two first circuit layers thereof.

The aforementioned method may further comprise a step of: forming two built-up structures respectively on two opposite surfaces of the core board structure, wherein the built-up structures has at least one dielectric layer, a second circuit layer disposed on the dielectric layer, and a plurality of conductive vias, the outmost second circuit layer has a plurality of conductive lands, and parts of the conductive vias are electrically connecting the circuits of the core board structure respectively. In addition, the aforementioned method may further comprise a step of: forming a solder mask on the surfaces of the built-up structures, and forming a plurality of openings on the solder masks to expose the conductive pads of the built-up structures.

In the present invention, the spaces between the circuits of every first circuit layer disposed on the high dielectric layer are filled with an adhesion layer, so the problem i.e., voids may be easily generated in the high dielectric material, can be solved. In addition, the reliability of the adhesion between the high dielectric material and a circuit layer can be improved, and the problem in which the high dielectric material easily cracks during the process of manufacture also can be solved.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view for illustrating a conventional packaging substrate with a capacitor embedded therein;

FIGS. 2A to 2F are cross-sectional views for illustrating a process of manufacturing the package structure of Embodiment 1 of the present invention; and

FIGS. 3A to 3B are cross-sectional views for illustrating a process of manufacturing the core board structure of Embodiment 2 of the present invention.

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

### Embodiment 1

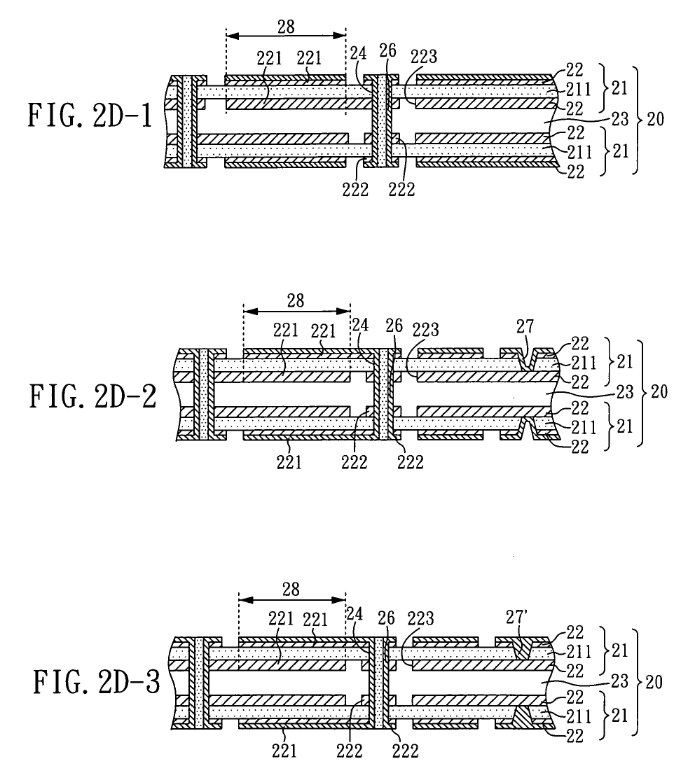

FIGS. 2A to 2F are cross-sectional views for illustrating a process of manufacturing the package structure of the present embodiment.

First, with reference to FIG. 2A, two capacitor disposition layers 21 are provided, and each of the capacitor disposition layers 21 consists of a high dielectric layer 211 and two metal layers 212 disposed on two opposite surfaces of the high dielectric layer 211. In other words, the capacitor disposition layers 21 are formed such that the high dielectric layer 211 is sandwiched in between two metal layers 212 by lamination. The material of the high dielectric layer 211 is selected form polymer material, ceramic material, polymer material filled with ceramic powders, or a combination thereof. For example, the material of the high dielectric layer 211 can be barium-tianate, lead-zirconate-tianate, or amorphous hydrogenated carbon dispersed in a binder.

With reference to FIG. 2B, the metal layers 212 of the capacitor disposition layers 21 are patterned by photolithography, which comprises exposing and developing, and etching. Then, a first circuit layer 22 is formed, which has a plurality of electrode plates 221 and a plurality of circuits 222.

With reference to FIG. 2C, an adhesive layer 23 is sandwiched in by lamination between the capacitor disposition layers 21 to adhere the capacitor disposition layers 21 to form a core board structure 20, wherein spaces 223 between the circuits 222 of every first circuit layer 22 are filled with the adhesive layer 23. Besides, the material of the adhesive layer 23 can be photosensitive or non-photosensitive rein, such as Ajinomoto Build-up Film (ABF), benzocyclo-buthene (BCB), liquid crystal polymer (LCP), poly-imide (PI), poly(phenylene ether) (PPE), poly(tetra-fluoroethylene) (PTFE), FR4, FR5, bismaleimide triazine (BT), or aramide. In addition, the material of the adhesive layer 23 can also be a material with epoxy resin and glass fiber.

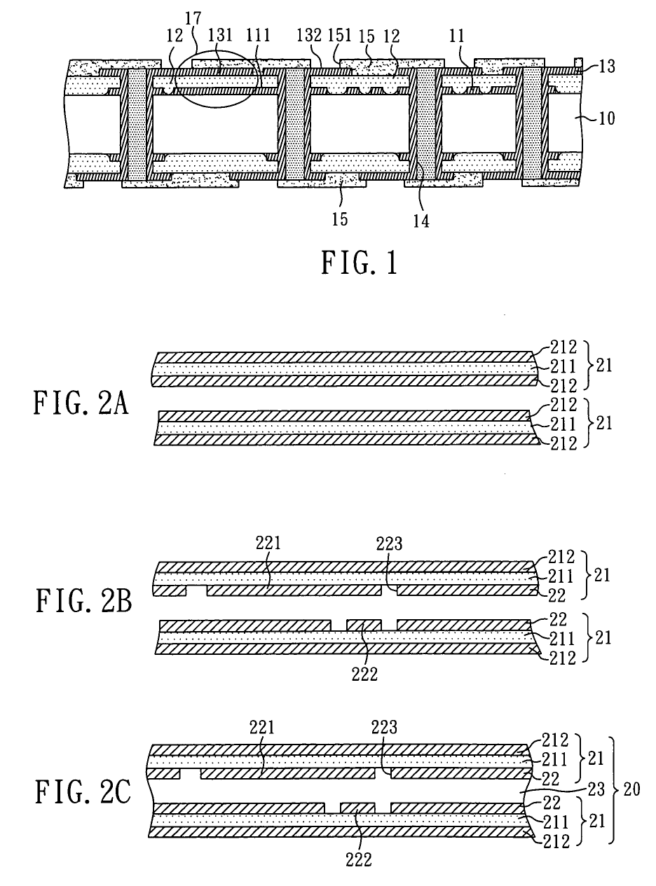

With reference to FIG. 2D-1, a plurality of through holes 24 penetrating the capacitor disposition layers 21 and the adhesive layer 23 are formed by drilling. Then, two first circuit layers 22 are formed on the metal layers 212 of a core board structure 20. Sequentially, the through holes 24 are processed to form a plurality of conductive through holes 26, which penetrate the capacitor disposition layers 21 and the adhesive layer 23. In this way, the conductive through holes 26 can electrically connect the circuits 222 of the capacitor disposition layers 21 and the circuits 222 of the core board structure 20. In addition, pairs of the electrode plates 221 on the opposite surfaces of each of the capacitor disposition layers 21 are parallel and correspond to each other to form capacitors 28. The method for manufacturing the first circuit layers 22 and the conductive through holes 26 can be any conventional method used in the art.

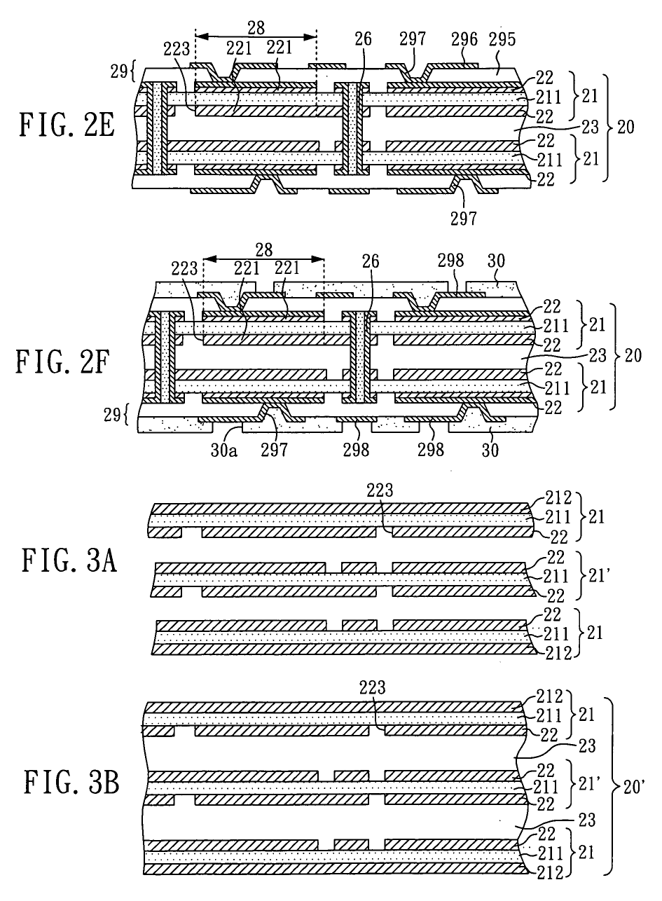

In addition, with reference to FIG. 2D-2 and FIG. 2D-3, in the present embodiment, conductive vias 27 (as shown in FIG. 2D-2) unfilled with metal, or conductive vias 27′ (as shown in FIG. 2D-3) filled with metal can also be formed in the high dielectric layers 211 of the capacitor disposition layers 21 to electrically connect the first circuit layers 22.

Therefore, a packaging substrate having capacitors embedded therein is obtained, which comprises: two capacitor disposition layers 21, each respectively consisting of a high dielectric layer 211 and two first circuit layers 22 disposed on two opposite surfaces of the high dielectric layer 211, wherein each of the first circuit layers 22 has a plurality of electrode plates 221 and a plurality of circuits 222; an adhesive layer 23 disposed between the capacitor disposition layers 21 to adhere the capacitor disposition layers 21 to form a core board structure 20, wherein spaces 223 between the circuits 222 of every first circuit layer 22 are filled with the adhesive layer 23; and a plurality of conductive through holes 26 penetrating the capacitor disposition layers 21 and the adhesive layer 23, and electrically connecting the circuits 222 of the capacitor disposition layers 21 respectively; wherein, pairs of the electrode plates 221 on the opposite surfaces of each of the capacitor disposition layers 21 are parallel and correspond to each other to form capacitors 28.

With reference to FIG. 2E, the aforementioned packaging substrate having capacitors embedded therein and the method for manufacturing the same can further comprise a built-up structure 29 formed on the two opposite surfaces of the core board structure 20. The built-up structure 29 comprises a dielectric layer 295, a second circuit layer 296 disposed on the dielectric layer 295, and a plurality of conductive vias 297. Furthermore, the outmost second circuit layer 296 of the built-up structure 29 has a plurality of conductive pads 298, and at least parts of the conductive vias 297 electrically connect to the first circuit layers 22 of the core board structure 20. In addition, with reference to FIG. 2F, a solder mask 30 is further formed on the surfaces of the built-up structures 29, wherein the solder mask 30 has a plurality of openings 30a to expose the conductive pads 298 of the two built-up structures 29.

### Embodiment 2

The method for manufacturing a packaging substrate is similar to the method illustrated in Embodiment 1. With reference to FIG. 3A and FIG. 3B, comparing to the packaging substrate of Embodiment 1, the packaging substrate of the present embodiment further comprises another capacitor disposition layer 21′, and two first circuit layers 22 are respectively formed on two opposite surfaces of the capacitor disposition layer 21′. Then, the capacitor disposition layer 21′ is disposed between two capacitor disposition layers 21, as shown in FIG. 3A. After two adhesion layers 23 are sandwiched in by lamination, the three capacitor disposition layers 21,21′ can adhere to each other to form a core board structure 20′, as shown in FIG. 3B, wherein spaces 223 between the circuits 222 of every first circuit layer 22 are filled with the adhesive layers 23. The following process for manufacturing the packaging substrate having capacitors embedded therein is the same as the process illustrated in Embodiment 1.

Although the present invention has been explained in relation to its preferred embodiment, it is to be understood that many other possible modifications and variations can be made without departing from the scope of the invention as hereinafter claimed.

What is claimed is:

1. A packaging substrate having capacitors embedded therein, comprising:
two capacitor disposition layers, each respectively consisting of a high dielectric layer and two first circuit layers disposed on two opposite surfaces of the high dielectric layer, wherein each of the first circuit layers has a plurality of electrode plates and a plurality of circuits;
an adhesive layer disposed between the capacitor disposition layers to adhere the capacitor disposition layers to form a core board structure, wherein spaces between the circuits of every first circuit layer are filled with the adhesive layer; and
a plurality of conductive through holes penetrating the capacitor disposition layers and the adhesive layer, and electrically connecting the circuits of the capacitor disposition layers respectively;
wherein, pairs of the electrode plates on the opposite surfaces of each of the capacitor disposition layers are parallel and correspond to each other to form capacitors.

2. The packaging substrate as claimed in claim 1, wherein the capacitor disposition layer further comprise a plurality of conductive vias to electrically connect the two first circuit layers of the capacitor disposition layer.

3. The packaging substrate as claimed in claim 1, further comprising two built-up structures respectively disposed on two opposite surfaces of the core board structure, wherein each of the two built-up structures comprises at least one dielectric layer, a second circuit layer disposed on the dielectric layer, and a plurality of conductive vias respectively, the outmost second circuit layer has a plurality of conductive pads, and at least parts of the conductive vias electrically connect to the first circuit layers of the core board structure.

4. The packaging substrate as claimed in claim 3, further comprising a solder mask disposed on the surfaces of the two built-up structures, wherein the solder mask has a plurality of openings to expose the conductive pads of the two built-up structures.

5. The packaging substrate as claimed in claim 1, wherein the material of the high dielectric layer is selected from polymer material, ceramic material, polymer material filled with ceramic powders, or a combination thereof.
